(19) United States
(12) Patent Application Publication
(10) Pub. No.: US 2009/0008801 A1
(43) Pub. Date: Jan. 8, 2009

(54) Semiconductor device and method for fabricating the same

(75) Inventors: Jeng-Yuan Lai, Taichung Hsien (TW); Chien-Ping Huang, Taichung (TW); Chun-Chi Ke, Taichung Hsien (TW); Yu-Po Wang, Taichung (TW); Chiao-Hung Yen, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 12/217,365

(22) Filed: Jul. 2, 2008

(30) Foreign Application Priority Data
Jul. 3, 2007 (TW) 096124083

(51) Int. Cl. H01L 23/52; H01L 21/00

(52) U.S. Cl. 257/782; 438/125; 257/E23.141; 257/E21.001

(57) ABSTRACT

This invention discloses a semiconductor device and a method for fabricating the same. The method includes providing a flexible carrier board having a first surface and a second surface opposite thereto; forming a metal lead layer and a first heat dissipating metal layer on the first surface of the flexible carrier board, and forming a second heat dissipating metal layer on the second surface of the flexible carrier board; providing a chip having an active surface and an opposed non-active surface, wherein a plurality of solder pads are formed on the active surface of the chip, each of the solder pads has a metal bump formed thereon and corresponding in position to the metal lead layer, and heat dissipating bumps are formed between the metal bumps corresponding in position to the first heat dissipating metal layer.

### FIELD OF THE INVENTION

The present invention relates to a semiconductor device and a method for fabricating the same, and more particularly, to a COF (chip-on-film) semiconductor device and a method for fabricating the same.

### BACKGROUND OF THE INVENTION

Conventionally, techniques for electrically connecting a chip to a flexible substrate using a flexible carrier board as a chip carrier include techniques such as Tape Carrier Package (TCP) and Chip on Film (COF) techniques. In order to alleviate heat dissipation issues related to the TCP technique, U.S. Pat. Nos. 6,297,074; 5,414,299; 4,849,857 and 5,095,404 disclose attaching a heat conducting element on the active or non-active surface of a chip to dissipate heat generated by the chip during operation.

However, in the traditional TCP technique, the minimum lead pitch is 35 μm, which does not satisfy the requirement in the industry for smaller pitch. Accordingly, a technique with smaller lead pitch, known as Chip on Film (COF), has been developed. In state-of-the-art COF technique, the minimum lead pitch can be as small as 20 μm; relevant details thereof can be found in U.S. Pat. Nos. 6,710,458; 6,559,524; and 6,864,119, for example.

FIGS. 4A to 4J are schematic diagrams illustrating a method for fabricating a conventional COF semiconductor device. First, as shown in FIGS. 4A to 4D, a chip 400 with a plurality of solder pads 401 is provided. An insulating layer 410 is formed to cover surface of the chip 400 and a plurality of openings 411 is formed in the insulating layer 410 to expose the solder pads 401. Then, a first electrically conducting layer 420 made of titanium tungsten (TiW) and a second electrically conducting layer 430 made of gold (Au) are formed on surface of the insulating layer 410 and in the openings 411 of the insulating layer 410 by technique such as sputtering.

Thereafter, the second electrically conducting layer 430 is covered by a resist layer 440, which is formed with a plurality of openings 441 for exposing part of the second electrically conducting layer 430 corresponding in position to the solder pads 401. Metal bumps 450 made of such as gold are then formed in the openings 441 of the resist layer 440 by method such as electroplating. The resist layer 440 and the first and second electrically conducting layers 420 and 430 covered by the resist layer 440 are then removed.

As shown in FIGS. 4E to 4I, a flexible carrier board 500 is provided. An electrically conducting layer 510 made of such as copper (Cu) is formed on surface of the carrier board 500 by method such as sputtering. A resist layer 520 is then formed on the electrically conducting layer 510, and a plurality of openings 521 corresponding to the metal bumps 450 of the chip 400 are formed in the resist layer 520. A metal lead layer 530 such as copper/tin (Cu/Sn) or copper/tin/gold (Cu/Sn/Au) is formed as fine pitch leads in the openings 521 of the resist layer 520 by electroplating, for example. Then, the resist layer 520 and the electrically conducting layer 510 covered by the resist layer 520 are removed. A solder proof layer 550 is then applied on the carrier board 500 and further processed to expose the metal lead layer 530.

As shown in FIG. 4J, the chip 400 and the carrier board 500 are joined together by thermal compression, that is, the metal (Au) bumps 450 of the chip and the metal (Sn) lead layer 530 of the carrier board form an eutectic structure, allowing them to be electrically connected to each other. Then, an underfill material 600 is filled into the gap between the chip 400 and the carrier board 500 to form a COF semiconductor device.

Although this method provides a finer lead pitch than the TCP technique, the traditional heat dissipating method cannot be applied to the COF semiconductor device due to structural changes. Furthermore, since COF semiconductor devices are fabricated in a reel-to-reel manner, if an external heat dissipating element is attached on the chip, the heat dissipating element would hinder reeling or reeling would cause damage of the heat dissipating element.

Therefore, there is an urgent need to provide effective heat dissipation for the COF semiconductor devices.

### SUMMARY OF THE INVENTION

In light of the foregoing drawbacks, an objective of the present invention is to provide a semiconductor device and a method for fabricating the same, which effectively dissipates heat generated by an operating chip in a COF semiconductor device.

Another objective of the present invention is to provide a semiconductor device and a method for fabricating the same, which enables effective heat dissipation of a COF semiconductor device while allowing reeling without damaging the heat dissipating element.

In accordance with the above and other objectives, the present invention provides a method for fabricating a semiconductor device, comprising: providing a chip having an active surface and a non-active surface opposite to each other and a flexible carrier board having a first surface and a second surface opposite to each other, wherein a plurality of solder pads is formed on the active surface of the chip, each of the solder pads has a metal bump formed thereon, and at least one heat dissipating bump is formed between the metal bumps, a metal lead layer corresponding to the metal bumps and a first heat dissipating metal layer corresponding to the heat dissipating bump are formed on the first surface of the flexible carrier board, and a second heat dissipating metal layer is formed on the second surface of the flexible carrier board; mounting the active surface of the chip to the first surface of the flexible carrier board such that the metal bumps and the heat dissipating bump on the active surface of the chip are electrically connected to the corresponding metal lead layer and the first heat dissipating metal layer, respectively; and filling an insulating gel between the chip and the flexible carrier board.

The method of forming the metal bumps and the heat dissipating bump of the chip comprises: providing the chip with an insulating layer formed on the active surface thereof, the insulating layer having a plurality of openings for exposing the solder pads of the chip; forming an electrically conducting layer on the insulating layer and in the openings; applying on the electrically conducting layer a resist layer, the resist layer having a plurality of first openings corresponding in position to the solder pads and at least one second opening between the first openings to expose the electrically conducting layer; electroplating to form the metal bumps and the heat dissipating bump in the first and second openings, respectively; and removing the resist layer and the electrically conducting layer covered by the resist layer.

The method of forming the metal lead layer and the first and second heat dissipating metal layers comprises: forming an electrically conducting layer on each of the first and second surfaces of the flexible carrier board; forming on the electrically conducting layer on the first surface a resist layer having third openings corresponding to the metal bumps of the chip and at least one fourth opening corresponding to the heat dissipating bump of the chip, and forming on the electrically conducting layer on the second surface a resist layer having at least one fifth opening; electroplating to form the metal lead layer and the first heat dissipating metal layer in the third and fourth openings respectively and form the second heat dissipating metal layer in the fifth opening; and removing the resist layer and the electrically conducting layer covered by the resist layer.

In addition, an electrically conducting structure can be formed in the flexible carrier board for electrically connecting the first and second heat dissipating metal layers, such that heat generated by the operating chip can be rapidly dissipated to the outside through the heat dissipating bump and the first and second heat dissipating metal layers.

The present invention also provides a semiconductor device, comprising: a flexible carrier board having a first surface and a second surface opposite to each other, wherein a metal lead layer and a first heat dissipating metal layer are formed on the first surface of the carrier board, and a second heat dissipating metal layer is formed on the second surface of the carrier board; a chip having an active surface and a non-active surface opposite to each other, wherein a plurality of solder pads is provided on the active surface of the chip, each of the solder pads has a metal bump formed thereon corresponding in position to the metal lead layer, and at least one heat dissipating bump is formed between the metal bumps and corresponding to the first heat dissipating metal layer of the flexible carrier board, such that the chip can be mounted to the metal lead layer and the first heat dissipating metal layer via the metal bumps and the heat dissipating bump, respectively; and an insulating gel filled between the chip and the flexible carrier board.

Furthermore, a solder proof layer is provided on the first surface of the flexible carrier board, exposing end portions of the metal lead layer and the first heat dissipating metal layer for electrical coupling of the chip.

Therefore, the semiconductor device and method for fabricating the same of the present invention essentially provides a flexible carrier board having a first surface and a second surface opposite to each other, with a metal lead layer and a first heat dissipating metal layer formed on the first surface of the flexible carrier board and a second heat dissipating metal layer formed on the second surface of the flexible carrier board; a chip having an active surface and a non-active surface opposite to each other, wherein the active surface is provided with a plurality of solder pads, each of the solder pads has a metal bump formed thereon corresponding in position to the metal lead layer, at least one heat dissipating bump is formed between the metal bumps corresponding to the first heat dissipating metal layer. Thus, when the chip is mounted to the flexible carrier board, the metal bumps of the chip are electrically connected to the corresponding metal lead layer of the flexible carrier board for signal propagation. Meanwhile, heat generated by the chip in operation can be transferred outside through the heat dissipating bump of the chip, the first heat dissipating metal layer of the flexible carrier board connected to the heat dissipating bump and the second heat dissipating metal layer on the second surface of the flexible carrier board, thereby improving heat dissipation. In this way, the present invention avoids the use of an external heat dissipating element as in the prior art that may hinder the reeling process of the semiconductor device and meanwhile avoids damage of the heat dissipation element caused by reeling.

### BRIEF DESCRIPTION OF THE DRAWINGS

The present invention can be more fully understood by reading the following detailed description of the preferred embodiments, with reference made to the accompanying drawings, wherein:

FIGS. 1A to 1I are schematic diagrams illustrating a first embodiment of a semiconductor device and a method for fabricating the same of the present invention;

FIGS. 2A to 2E are schematic diagrams illustrating a second embodiment of a semiconductor device and a method for fabricating the same of the present invention;

FIG. 3 is a schematic diagram illustrating a third embodiment of a semiconductor device of the present invention; and

FIGS. 4A to 4J are schematic diagrams illustrating a method for fabricating a conventional COF semiconductor device.

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

### First Embodiment

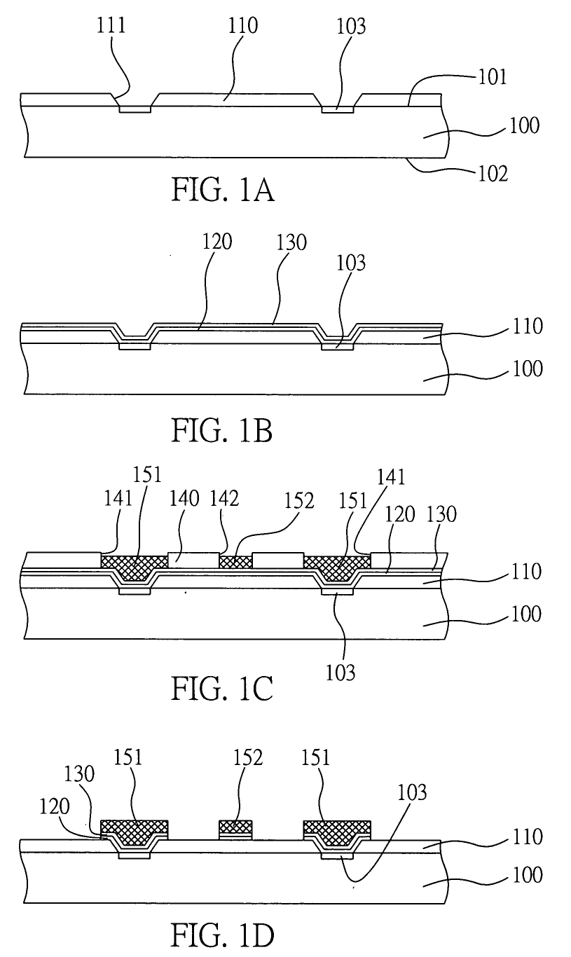

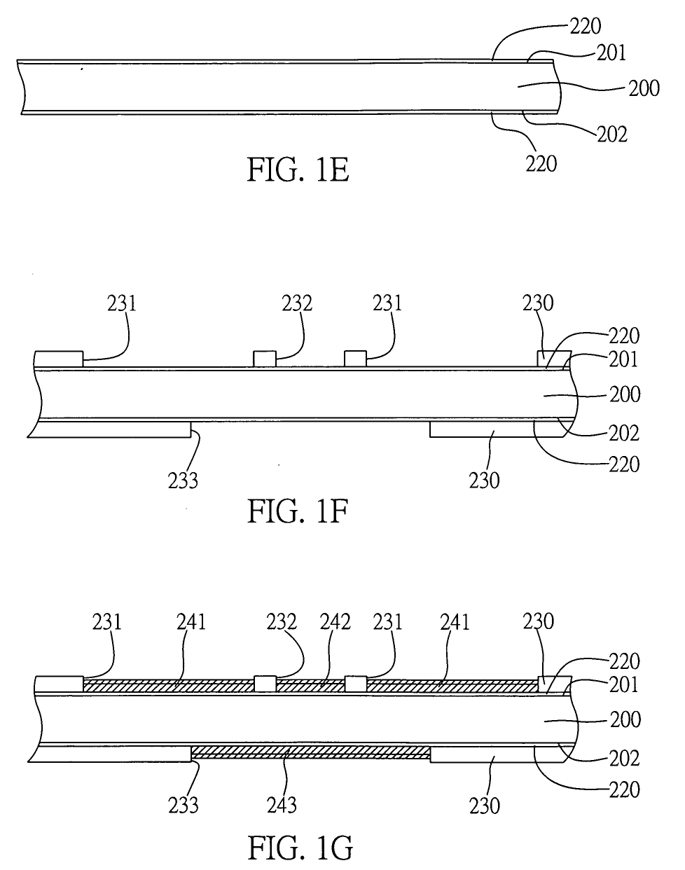

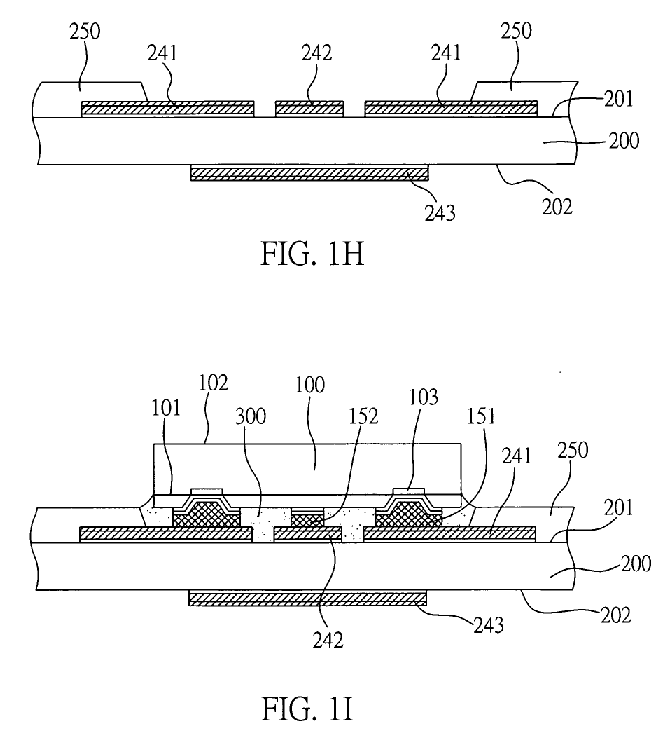

FIGS. 1A to 1I are schematic diagrams illustrating a first embodiment of a semiconductor device and a method for fabricating the same of the present invention.

As shown in FIG. 1A, a chip 100 having an active surface 101 and a non-active surface 102 opposite to the active surface 101 is provided. A plurality of solder pads 103 is formed on the active surface 101 of the chip 100, an insulating layer 110 is formed to cover the active surface 101 and a plurality of openings 111 is formed in the insulating layer 110 to expose the solder pads 103.

As shown in FIG. 1B, a first electrically conducting layer 120 made of titanium tungsten (TiW) and a second electrically conducting layer 130 made of gold (Au) are formed on surface of the insulating layer 110 and in the openings 111 by technique such as sputtering.

As shown in FIGS. 1C and 1D, a resist layer 140 is formed on the second electrically conducting layer 130. A plurality of first openings 141 is formed in the resist layer 140 corresponding in position to the solder pads 103 of the chip 100, and at least a second opening 142 is formed between the first openings 141, such that the second electrically conducting layer 130 is exposed from the first openings 141 and the second opening 142. Then, metal bumps 151 made of such as gold (Au) and at least one heat dissipating bump 152 are formed in the first openings 141 and the second opening 142, respectively, by method such as electroplating. The resist layer 140 and the first and second electrically conducting layers 120 and 130 covered by the resist layer 140 are then removed. Therein, the metal bumps 151 are disposed on the solder pads 103.

The metal bumps 151 are connected to the solder pads 103 of the chip 100, allowing external electrical coupling of the chip 100. The first and second electrically conducting layers 120 and 130 located between the metal bumps 151 and the solder pads 103 of the chip 100 can be considered as under-bump metallization (UBM) layers. Whereas the heat dissipating bump 152 is formed on the active surface of the chip 100 and not connected to the solder pads 103, so it can be considered as a dummy bump.

As shown in FIG. 1E, a flexible carrier board 200, such as a polyimide (PI) tape, is provided and processed in a reel-to-reel manner. The flexible carrier board 200 has a first surface 201 and a second surface 202 opposite to each other. An electrically conducting layer 220 made of such as copper (Cu) is formed on each of the first and second surfaces 201 and 202 of the flexible carrier board 200 by method such as sputtering.

As shown in FIG. 1F, a resist layer 230 is then formed on the electrically conducting layer 220. Third openings 231 and at least one fourth opening 232 are formed in the resist layer 230 on the first surface 201 of the flexible carrier board 200 corresponding to the metal bumps 151 and the heat dissipating bump 152, respectively. At least one fifth opening 233 is formed in the resist layer 230 on the second surface 202 of the flexible carrier board 200.

As shown in FIG. 1H, a metal lead layer 241 and a first heat dissipating metal layer 242 are formed in the third openings and the fourth opening 231 and 232, respectively, by electroplating, and a second heat dissipating metal layer 243 is formed in the fifth opening 233 by electroplating. The metal lead layer 241 and the first and second heat dissipating metal layers 242 and 243 are, for example, Cu/Sn layers, having a thickness of about 6 to 15 μm.

As shown in FIG. 1H, the resist layer 230 and the electrically conducting layer 220 covered by the resist layer 230 are removed. A solder proof layer 250 is applied on the first surface 201 of the flexible carrier board 200, which exposes the first heat dissipating metal layer 242 and end portions of the metal lead layer 241 for electrically connecting the metal bumps 151 of the chip 100.

As shown in FIG. 1I, the active surface 101 of the chip 100 and the first surface 201 of the flexible carrier board 200 are joined together, that is, the metal bumps 151 and the heat dissipating bump 152 on the active surface 101 of the chip 100 are thermally compressed with the corresponding metal lead layer 241 and the first heat dissipating metal layer 242 on the first surface 201 of the flexible carrier board 200 so as to form an eutectic structure. The chip 100 is thus allowed to propagate signals through its metal bumps 151 and the metal lead layer 241 of the carrier board 200. Meanwhile, heat generated by the chip 100 during operation can be effectively dissipated through its heat dissipating bump (dummy bump) 152, the first heat dissipating metal layer 242 on the first surface 201 of the carrier board 200 and the second heat dissipating metal layer 243 on the second surface 202 of the carrier board 200.

Then, an insulating gel 300 is filled as an underfill material into the gap between the chip 100 and the flexible carrier board 200 to form a COF semiconductor device of the present invention.

According to the above-described fabrication method, the present invention further discloses a semiconductor device, comprising: a flexible carrier board 200 having a first surface 201 and a second surface 202 opposite to each other, wherein, a metal lead layer 241 is formed on the first surface 201 and a first heat dissipating metal layer 242 is formed between the metal lead layer 241, and a second heat dissipating metal layer 243 is formed on the second surface 202; a chip 100 having an active surface 101 and a non-active surface 102 opposite to each other, wherein the active surface 101 of the chip 100 is provided with a plurality of solder pads 103, each of the solder pads 103 has a metal bump 151 formed thereon corresponding in position to the metal lead layer 241 of the flexible carrier board 200, at least one heat dissipating bump 152 is formed between the metal bumps 151 and corresponding to the first heat dissipating metal layer 242 of the flexible carrier board 200, such that the chip 100 is mounted on the metal lead layer 241 and the first heat dissipating layer 242 of the flexible carrier board 200 via the metal bumps 151 and the heat dissipating bump 152; and an insulating gel 300 for filling the gap between the chip 100 and the flexible carrier board 200.

In addition, a solder proof layer 250 is further formed on the first surface 201 of the flexible carrier board 200, exposing the metal lead layer 241 and the first heat dissipating metal layer 242; an insulating layer 110 exposing the solder pads 103 is formed on the active surface 101 of the chip 100; and electrically conducting layers 120 and 130 are interposed between the solder pads 103 and the metal bumps 151 and between the active surface 101 of the chip 100 and the heat dissipating bump 152.

Therefore, the semiconductor device and method for fabricating the same of the present invention essentially provides a flexible carrier board having a first surface and a second surface opposite to each other, with a metal lead layer and a first heat dissipating metal layer formed on the first surface of the flexible carrier board, and a second heat dissipating metal layer formed on the second surface of the flexible carrier board; a chip having an active surface and a non-active surface opposite to each other, wherein the active surface of the chip is provided with a plurality of solder pads, each of the solder pads has a metal bump formed thereon corresponding in position to the metal lead layer, at least one heat dissipating bump is formed between the metal bumps and corresponding to the first heat dissipating metal layer. When the chip is mounted to the flexible carrier board, the metal bumps of the chip are connected to the corresponding metal lead layer of the flexible carrier board for signal propagation. Meanwhile, heat generated by the chip in operation can be transferred outside through the heat dissipating bump of the chip, the first heat dissipating metal layer of the flexible carrier board connected to the heat dissipating bump and the second heat dissipating metal layer on the second surface of the flexible carrier board, thereby improving heat dissipation.

### Second Embodiment

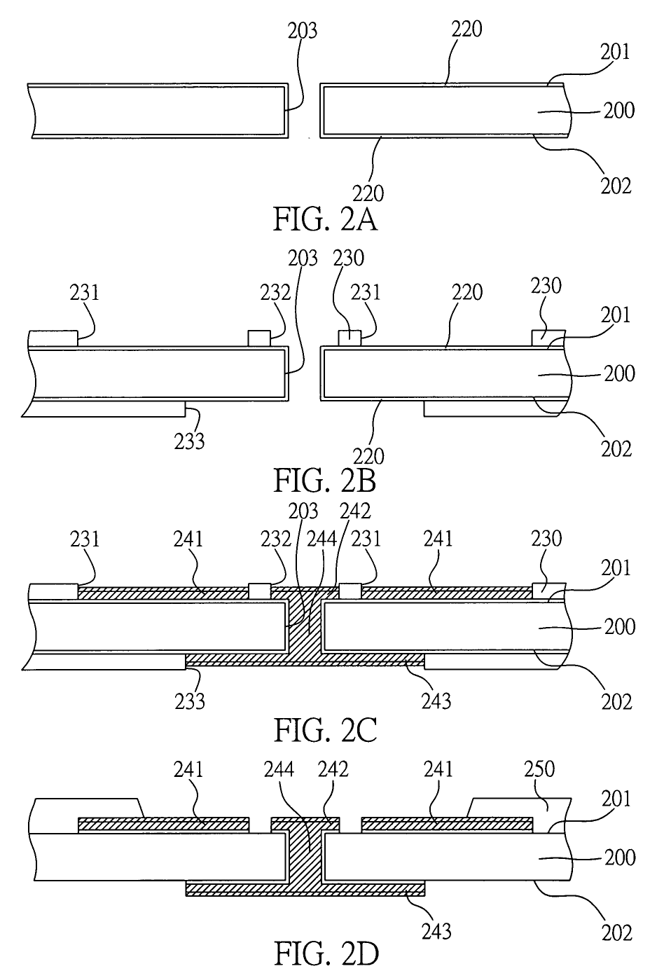

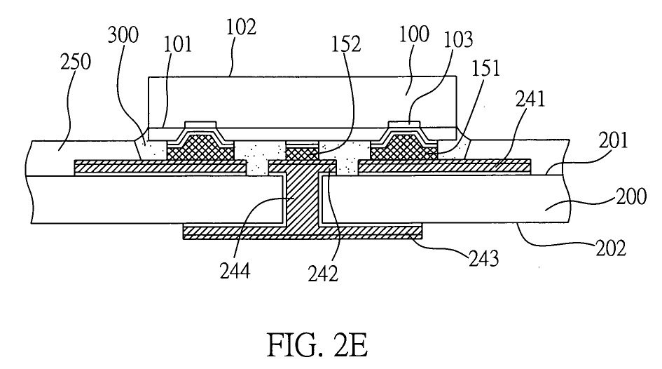

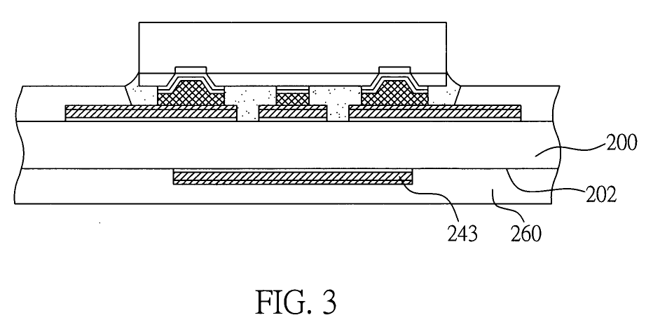

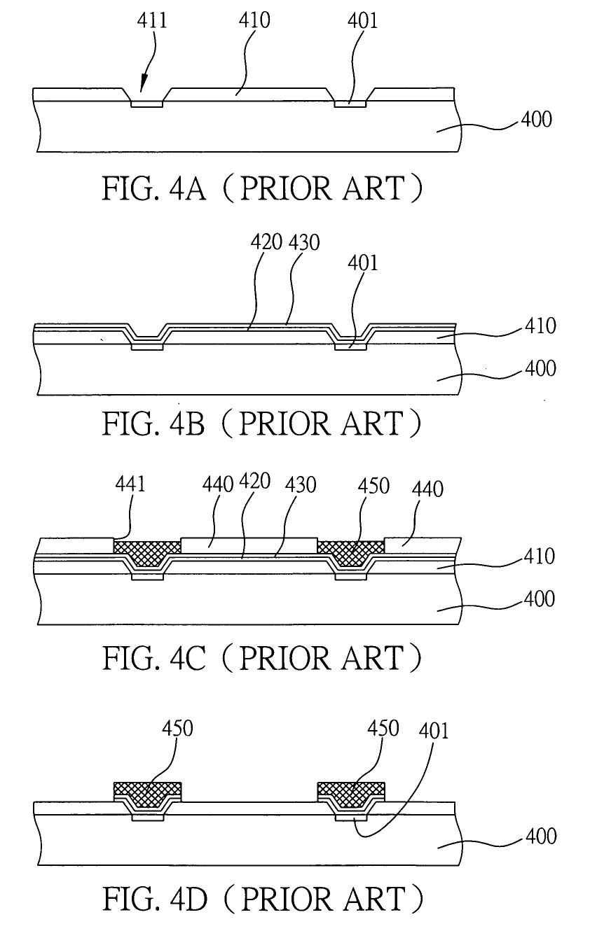

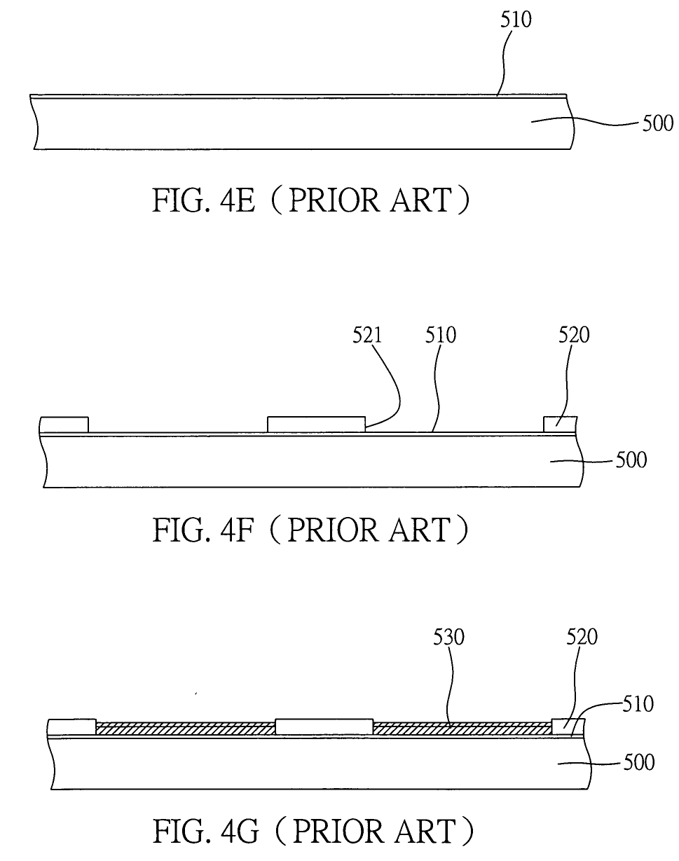

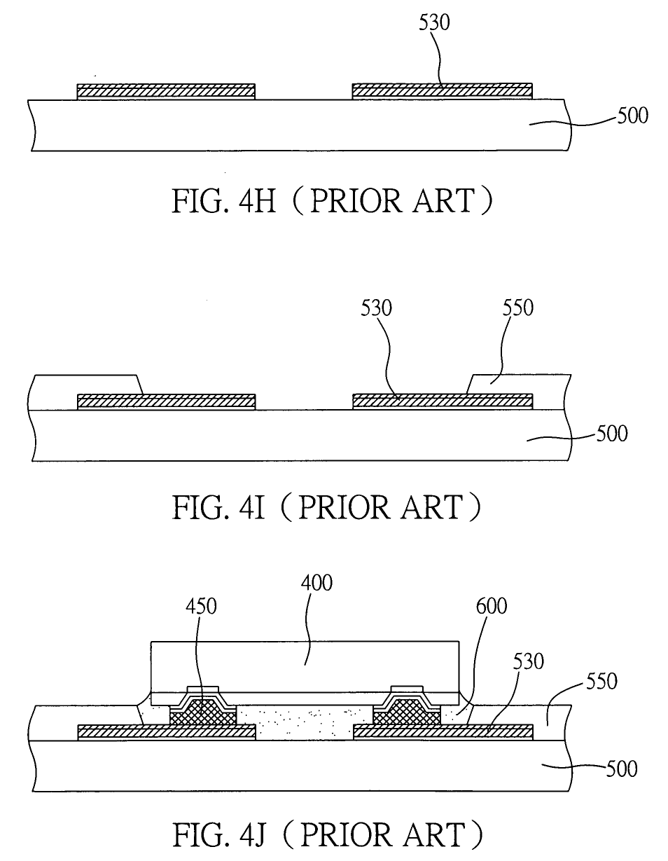

Referring to FIGS. 2A to 2E, which are schematic diagrams illustrating a second embodiment of a semiconductor device and a method for fabricating the same of the present invention. For simplicity and clarity of the drawings, elements that are similar to or the same as those of the previous embodiment are denoted by same reference numerals.

The semiconductor device and its fabricating method in this embodiment are similar to the previous embodiment; the main difference is given as follows. Referring to FIG. 2A, a through hole 203 is formed in a flexible carrier board 200 having a first surface 201 and a second surface 202 opposite to each other. An electrically conducting layer 220 made of such as copper is applied on each of the first and second surfaces 201 and 202 and the surface of the through hole 203 of the carrier board 200 by sputtering, for example.

As shown in FIG. 2B, a resist layer 230 is formed on the electrically conducting layer 220. The resist layer 230 on the first surface 201 of the flexible carrier board 200 is formed with third openings 231 and at least one fourth opening 232 corresponding to the metal bumps and the heat dissipating bump of the chip respectively, and the resist layer 230 on the second surface 202 of the flexible carrier board 200 is formed with a fifth opening 233, wherein the fourth and fifth openings 232 and 233 are connected with the through hole 203.

As shown in FIG. 2C, a metal lead layer 241, a first heat dissipating metal layer 242 and a second heat dissipating metal layer 243 are formed in the third openings 231, the fourth opening 232 and the fifth opening 233, respectively, by electroplating. In addition, an electrically conducting structure 244 is electroplated in the through hole 203, such that the first heat dissipating metal layer 242 on the first surface 201 can be electrically connected to the second heat dissipating metal layer 243 on the second surface 202 of the flexible carrier board.

As shown in FIG. 2D, the resist layer 230 and the electrically conducting layer 220 covered by the resist layer 230 are removed. A solder proof layer 250 is disposed on the first surface 201 of the flexible carrier board 200, further allowing the first heat dissipating metal layer 242 and end portions of the metal lead layer 241 to be exposed from the solder proof layer 250.

As shown in FIG. 2E, the active surface 101 of the chip 100 having the metal bumps 151 and the heat dissipating bump 152 and the flexible carrier board 200 are joined together, that is, the metal bumps 151 and the heat dissipating bump 152 on the active surface 101 of the chip 100 are thermally compressed with the corresponding metal lead layer 241 and the first heat dissipating metal layer 242 on the first surface 201 of the flexible carrier board 200 so as to form an eutectic structure. The chip 100 is thus allowed to propagate signals through the metal bumps 151 and the metal lead layer 241 of the carrier board. Meanwhile, heat generated by the chip 100 during operation can be effectively dissipated through the heat dissipating bump (dummy bump) 152, the first heat dissipating metal layer 242 on the first surface 201 of the carrier board 200, the electrically conducting structure 244 in the carrier board 200, and the second heat dissipating metal layer 243 on the second surface 202 of the carrier board 200.

Then, an insulating gel 300 is filled as an underfill material into the gap between the chip 100 and the flexible carrier board 200 to form a COF semiconductor device of the present invention.

### Third Embodiment

Referring to FIG. 3, which is a schematic diagram illustrating a third embodiment of a semiconductor device of the present invention. For simplicity and clarity of the drawings, elements that are similar or the same with those of the previous embodiments are denoted by same reference numerals.

The semiconductor device and its fabricating method in this embodiment are similar to the previous embodiment; the main difference is that a cover layer 260 is further formed on the second surface 202 of the flexible carrier board 200 to cover the second heat dissipating metal layer 243. The cover layer 260 is for example a solder proof layer.

The above embodiments are only used to illustrate the principles of the present invention, and they should not be construed as to limit the present invention in any way. The above embodiments can be modified by those with ordinary skills in the arts without departing from the scope of the present invention as defined in the following appended claims.

What is claimed is:

1. A method for fabricating a semiconductor device, comprising the steps of:
providing a chip having an active surface and a non-active surface opposite to each other and a flexible carrier board having a first surface and a second surface opposite to each other, wherein a plurality of solder pads are formed on the active surface of the chip, each of the solder pads has a metal bump formed thereon, and at least one heat dissipating bump is formed between the metal bumps, a metal lead layer corresponding to the metal bumps and a first heat dissipating metal layer corresponding to the heat dissipating bump are formed on the first surface of the flexible carrier board, and a second heat dissipating metal layer is formed on the second surface of the flexible carrier board;
mounting the active surface of the chip to the first surface of the flexible carrier board such that the metal bumps and the heat dissipating bump on the active surface of the chip are electrically connected to the corresponding metal lead layer and the first heat dissipating metal layer, respectively; and
filling a gap between the chip and the flexible carrier board with an insulating gel.

2. The method for fabricating a semiconductor device of claim 1, further comprising the steps of:
providing the chip having an insulating layer formed on the active surface thereof, wherein the insulating layer has a plurality of openings for exposing the solder pads;
forming an electrically conducting layer on the insulating layer and in the openings;
forming a resist layer on the electrically conducting layer, wherein the resist layer has a plurality of first openings corresponding in position to the solder pads and at least one second opening between the first openings for exposing the electrically conducting layer;
electroplating to form the metal bumps and the heat dissipating bump in the first and second openings, respectively; and
removing the resist layer and the electrically conducting layer covered by the resist layer.

3. The method for fabricating a semiconductor device of claim 2, wherein the electrically conducting layer has a TiW/Au structure, the metal bumps and the heat dissipating bump are made of gold, and the metal bumps are formed on the solder pads.

4. The method for fabricating a semiconductor device of claim 1, further comprising the steps of:
forming an electrically conducting layer on the first and second surfaces of the flexible carrier board;
forming a resist layer covering the electrically conducting layer, wherein the resist layer on the first surface is formed with third openings corresponding to the metal bumps of the chip and at least one fourth opening corresponding to the heat dissipating bump of the chip, and wherein the resist layer on the second surface is formed with at least one fifth opening;
electroplating to form the metal lead layer and the first heat dissipating metal layer in the third and fourth openings respectively and form the second heat dissipating metal layer in the fifth opening; and
removing the resist layer and the electrically conducting layer covered by the resist layer.

5. The method for fabricating a semiconductor device of claim 1, further comprising the steps of:
forming at least one through hole in the flexible carrier board and forming an electrically conducting layer covering first and second surfaces of the flexible carrier board and the through hole;
forming a resist layer on the electrically conducting layer, wherein the resist layer on the first surface of the flexible carrier board has third openings formed corresponding to the metal bumps and at least one fourth opening formed corresponding to the heat dissipating bump, the resist layer on the second surface of the flexible carrier board has at least one fifth opening, and the fourth opening and the fifth opening are connected to the through hole of the flexible carrier board;
electroplating to form the metal lead layer, the first heat dissipating metal layer and the second heat dissipating metal layer in the third, fourth and fifth openings, respectively, and form an electrically conductive structure in the through hole to electrically connect the first heat dissipating metal layer on the first surface and the second heat dissipating metal layer on the second surface of the flexible carrier board; and
removing the resist layer and the electrically conducting layer covered by the resist layer.

6. The method for fabricating a semiconductor device of claim 1, wherein the metal bumps are connected to the solder pads for electrically coupling the chip to an external device, while the heat dissipating bump formed on the active surface of the chip is not connected to the solder pads and accordingly is a dummy bump.

7. The method for fabricating a semiconductor device of claim 1, wherein the flexible carrier board is a polyimide (PI) tape and processed in a reel-to-reel manner.

8. The method for fabricating a semiconductor device of claim 1, wherein the metal lead layer and the first and second heat dissipating metal layers are made of copper/tin (Cu/Sn), and have a thickness of 6 to 15 μm.

9. The method for fabricating a semiconductor device of claim 1, wherein the metal bumps and the heat dissipating bump on the active surface of the chip are thermally compressed with the corresponding metal lead layer and the first heat dissipating metal layer on the first surface of the flexible carrier board so as to form an eutectic structure.

10. The method for fabricating a semiconductor device of claim 1, wherein signal from the chip propagates through the metal bumps and the metal lead layer, and heat generated by the chip during operation is dissipated through the heat dissipating bump, the first heat dissipating metal layer on the first surface of the carrier board and the second heat dissipating metal layer on the second surface of the carrier board.

11. The method for fabricating a semiconductor device of claim 1, wherein the first surface of the flexible carrier board is covered with a solder proof layer, and end portions of the metal lead layer and the first heat dissipating metal layer are exposed.

12. The method for fabricating a semiconductor device of claim 1, wherein a cover layer is further provided for covering the second heat dissipating metal layer on the second surface of the flexible carrier board.

13. The method for fabricating a semiconductor device of claim 12, wherein the cover layer is a solder proof layer.

14. A semiconductor device, comprising:
a flexible carrier board having a first surface and a second surface opposite to each other, wherein a plurality of metal lead layers are formed on the first surface of the flexible carrier board, a first heat dissipating metal layer is formed between the metal lead layers, and a second heat dissipating metal layer is formed on the second surface of the flexible carrier board;
a chip having an active surface and a non-active surface opposite to each other, wherein a plurality of solder pads are disposed on the active surface of the chip, a metal bump is formed on each of the solder pads corresponding in position to the metal lead layers, and at least one heat dissipating bump is formed between the metal bumps and corresponding to the first heat dissipating metal layer of the flexible carrier board, such that the chip is mounted to the metal lead layer and the first heat dissipating metal layer via the metal bumps and the heat dissipating bump, respectively; and
an insulating gel filled between the chip and the flexible carrier board.

15. The semiconductor device of claim 14, wherein an insulating layer exposing the solder pads is formed on the active surface of the chip, and an electrically conducting layer is provided between the solder pads and the metal bumps and between the active surface of the chip and the heat dissipating bump.

16. The semiconductor device of claim 15, wherein the electrically conducting layer is an under-bump metallization (UBM) layer having a TiW/Au structure.

17. The semiconductor device of claim 14, wherein an electrically conducting structure is formed in the flexible carrier board for electrically connecting the first and second heat dissipating metal layers.

18. The semiconductor device of claim 14, wherein the metal bumps are connected to the solder pads for electrically coupling the chip to an external device, while the heat dissipating bump formed on the active surface of the chip is not connected to the solder pads and accordingly is a dummy bump.

19. The semiconductor device of claim 14, wherein the flexible carrier board is a polyimide (PI) tape.

20. The semiconductor device of claim 14, wherein the metal lead layers and the first and second heat dissipating metal layers are made of copper/tin (Cu/Sn) and have a thickness of 6 to 15 μm, and the metal bumps and the heat dissipating bump are made of gold (Au).

21. The semiconductor device of claim 14, wherein the metal bumps and the heat dissipating bump on the active surface of the chip form an eutectic structure with the corresponding metal lead layer and the first heat dissipating metal layer on the first surface of the flexible carrier board.

22. The semiconductor device of claim 14, wherein signal from the chip propagates through the metal bumps and the metal lead layer, and heat generated by the chip during operation is dissipated through the heat dissipating bump, the first heat dissipating metal layer on the first surface of the carrier board and the second heat dissipating metal layer on the second surface of the carrier board.

23. The semiconductor device of claim 14, further comprising a solder proof layer covering the first surface of the flexible carrier board and exposing end portions of the metal lead layers and the first heat dissipating metal layer.

24. The semiconductor device of claim 14, further comprising a cover layer formed on the second surface of the flexible carrier board and covering the second heat dissipating metal layer.

25. The semiconductor device of claim 24, wherein the cover layer is a solder proof layer.
